(19) United States
(12) Patent Application Publication
(10) Pub. No.: US 2021/0201473 A1
(43) Pub. Date: Jul. 1, 2021

(54) SYSTEM AND METHOD FOR MEASUREMENT OF INFLATION PRESSURE AND LOAD OF TIRES FROM THREE-DIMENSIONAL (3D) GEOMETRY MEASUREMENTS

(71) Applicant: Photogauge, Inc., Belmont, CA (US)

(72) Inventors: Arunnelson XAVIER, Alamo, CA (US); Sameer SHARMA, Alamo, CA (US); Devendiran RENUGOPAL, Alamo, CA (US); Sankara J. SUBRAMANIAN, Alamo, CA (US)

(21) Appl. No.: 17/203,943

(22) Filed: Mar. 17, 2021

Related U.S. Application Data
(63) Continuation-in-part of application No. 17/128,141, filed on Dec. 20, 2020.
Application No. 17/128,141 is a continuation of application No. 16/023,449, filed on Jun. 29, 2018, now Pat. No. 10,885,622.
Application No. 16/023,449 is a continuation-in-part of application No. 16/131,456, filed on Sep. 14, 2018.
Application No. 16/131,456 is a continuation-in-part of application No. 16/023,449, filed on Jun. 29, 2018, now Pat. No. 10,885,622.

(51) Int. Cl. G06T 7/00; G06T 7/30; G06K 9/00; G06F 30/17

(52) U.S. Cl. CPC G06T 7/0004; G06F 30/17; G06K 9/00671; G06T 7/30

(57) ABSTRACT

A system and method for measurement of inflation pressure and load of tires from three-dimensional (3D) geometry measurements are disclosed. An example embodiment is configured to receive a unique tire signature of a vehicle tire under analysis from a perception capture system; match the received unique signature of the vehicle tire under analysis with one or more baseline tire signature elements of a baseline tire signature database; associate an inflation pressure and compressive tire load of the one or more matching baseline tire signature elements with the vehicle tire under analysis; compare the inflation pressure and compressive tire load associated with the vehicle tire under analysis with data indicative of safe operating ranges for the vehicle tire under analysis in relevant environmental conditions; and automatically send a user notification to alert a user to a detection of an unsafe tire condition if the inflation pressure or compressive tire load associated with the vehicle tire under analysis is outside of a safe operating range for the vehicle tire under analysis.

### PRIORITY PATENT APPLICATIONS

This is a continuation-in-part (CIP) patent application claiming priority to U.S. non-provisional patent application Ser. No. 17/128,141, filed on Dec. 20, 2020; which is a continuation application of patent application Ser. No. 16/023,449, filed on Jun. 29, 2018. This is also a CIP patent application claiming priority to U.S. non-provisional patent application Ser. No. 16/131,456, filed on Sep. 14, 2018; which is a CIP of patent application Ser. No. 16/023,449, filed on Jun. 29, 2018. This present patent application draws priority from the referenced patent applications. The entire disclosure of the referenced patent applications is considered part of the disclosure of the present application and is hereby incorporated by reference herein in its entirety.

### COPYRIGHT

A portion of the disclosure of this patent document contains material that is subject to copyright protection. The copyright owner has no objection to the facsimile reproduction of the patent document or the patent disclosure, as it appears in the Patent and Trademark Office patent files or records, but otherwise reserves all copyright rights whatsoever. The following notice applies to the disclosure provided herein and to the drawings that form a part of this document: Copyright 2018-2021 PhotoGAUGE, Inc., All Rights Reserved.

### TECHNICAL FIELD

This patent application relates to computer-implemented software systems, metrology systems, photogrammetry-based systems, and automatic visual measurement or inspection systems, according to example embodiments, and more specifically to a system and method for measurement of inflation pressure and load of tires from three-dimensional (3D) geometry measurements.

### BACKGROUND

Inflation pressure and compressive load on vehicle tires have a strong influence on their mechanical performance. Therefore, predicting tire performance depends critically on precise measurement of these quantities. However, such measurements are not easily performed in the field where tires are commonly used, e.g. on a highway or in an underground mine.

While there are pressure gauges and remote tire pressure sensors (commonly referred to as Tire Pressure Measurement Systems, or TPMS) to measure inflation pressure, the former is a contact type measurement requiring manual operation while the latter represents an investment for the tire owner. Measurement of compressive load on a tire is much more difficult in general as there are no direct compressive load measurement tools available.

Often, one can arrive at an average load knowing the total load on the vehicle and the number and distribution of tires on the vehicle. However, such techniques are too simplistic for measurement of the individual compressive load on a specific tire on a vehicle when the distribution of the load on the vehicle is asymmetric. Asymmetric loading is common in construction and mining vehicles (e.g., in mining trucks carrying excavated ores), which can be oddly shaped.

More recently, sensors such as accelerometers have been built into tires and empirical relationships derived to compute tire loads from accelerometer data obtained during use. However, these techniques suffer from the same drawbacks as TPMS, i.e., the additional cost of this technology.

### SUMMARY

In various example embodiments described herein, a system and method for measurement of inflation pressure and load of tires from three-dimensional (3D) geometry measurements are disclosed. In the various example embodiments described herein, a tire analysis tool is provided to address the shortcomings of the conventional technologies for measurement of inflation pressure and compressive loads on tires as described above. In the various example embodiments, systems and methods are disclosed for calculating vehicle tire inflation pressure and compressive load from a set of still images or a video clip, thus enabling non-contact measurements anywhere anytime.

For any given vehicle tire design (e.g., the composition, geometry, and usage of the tire), the inflation pressure and compressive load produce a unique tire signature related to the 3D shape of the tire. This unique tire signature is therefore associated with the inflation pressure and compressive load of a particular tire at a moment in time when the unique tire signature is captured. An accurate capture and measurement of the 3D shape of at least a portion of the tire (e.g., the unique tire signature) can be used to determine and associate the unique combination of pressure and compressive load that produces the measured 3D shape of the tire.

In the various example embodiments described herein, accurate capture of the 3D tire shapes (e.g., capture of the unique tire signature) can be obtained by a variety of means, including: white-light scanners, LiDAR (Light Detection and Ranging technology), cameras, infrared (IR) or thermal imaging systems, photogrammetry-based reconstructions, and the like. As disclosed herein, many of these unique tire signature capture systems can be installed in or on a vehicle to automatically capture the 3D shape of the vehicle tire without human intervention. As described in more detail below, the data associated with the capture of the unique tire signature of a vehicle tire can be analyzed and the current inflation pressure and load on the tire can be determined in real-time, without human intervention, and without contact with the tire. Details of the various example embodiments are provided below.

### BRIEF DESCRIPTION OF THE DRAWINGS

The various embodiments are illustrated by way of example, and not by way of limitation, in the figures of the accompanying drawings in which:

FIGS. 1 and 2 illustrate sample views of a 3D scan of a tire portion as generated from images captured as perception data;

FIG. 3 is a sample view of a tire showing a deviation map indicating specific values of deviation between the 3D shape of the tire under analysis and the 3D shape of a corresponding baseline tire;

FIG. 4 is a structure diagram that illustrates example embodiments of systems as described herein;

FIG. 5 is a processing flow diagram that illustrates example embodiments of methods as described herein; and

FIG. 6 shows a diagrammatic representation of a machine in the example form of a computer system within which a set of instructions when executed may cause the machine to perform any one or more of the methodologies discussed herein.

### DETAILED DESCRIPTION

In the following description, for purposes of explanation, numerous specific details are set forth in order to provide a thorough understanding of the various embodiments. It will be evident, however, to one of ordinary skill in the art that the various embodiments may be practiced without these specific details.

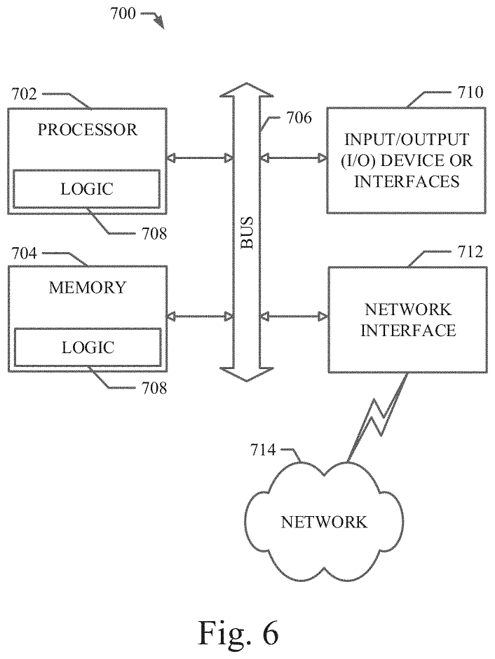

In various example embodiments described herein, a system and method for measurement of inflation pressure and load of tires from three-dimensional (3D) geometry measurements are disclosed. In the various example embodiments described herein, a tire analysis system can be implemented on a computing platform, such as the computing platform described below in connection with FIG. 6. Additionally, the tire analysis system of an example embodiment can be implemented with an imaging system or perception data capture capability to capture the unique tire signature of one or more vehicle tires. However, an imaging system or perception data capture capability is not a required part of the tire analysis system as the tire analysis system can use images or perception data of one or more vehicle tires that can be captured independently or separately from the tire analysis system.

In the various example embodiments described herein, accurate capture of the 3D tire shapes (e.g., capture of the unique tire signature) can be obtained by a variety of perception sensing means, including: white-light scanners, LiDAR (Light Detection and Ranging technology), cameras, photogrammetry-based reconstructions, X-ray imaging devices, thermal imaging devices, Radar devices, acoustic data receivers, lasers, and the like. A white light scanner (WLS) is a well-known device for performing surface height measurements of an object using coherence scanning interferometry (CSI) with spectrally-broadband “white light” illumination. LiDAR is a well-known technology for measuring distances by illuminating the target with laser light and measuring the reflection with a sensor. Differences in laser return times and wavelengths can then be used to make digital 3D representations of the target. Photogrammetry refers to the science of making measurements from photographs or images. The input to photogrammetry is typically photographs or images, and the output is typically a map, a drawing, a measurement, or a three-dimensional (3D) model of some real-world object or scene captured in the photographs or images. It will be apparent to those of ordinary skill in the art in view of the disclosure herein that other well-known perception data capture technologies can be used to capture the unique signature of a vehicle tire in real-time, without human intervention, and without contact with the tire. As disclosed herein, many of these unique tire signature capture systems can be installed in or on a vehicle to automatically capture the 3D shape of the vehicle tire. In addition to tire shape, the unique tire signature can also be based on the capture of a set of points of the tire from various types of sensors, including the perception sensing devices listed above. For example, a unique tire signature can be based on a set of acoustic pulses applied to a tire at various points on the tire and receiving the acoustic returns from the set of points. As described in more detail below, the data associated with the capture of the unique tire signature of a vehicle tire can be analyzed by the tire analysis system and the current inflation pressure and load on the tire can be determined in real-time, without human intervention, and without contact with the tire.

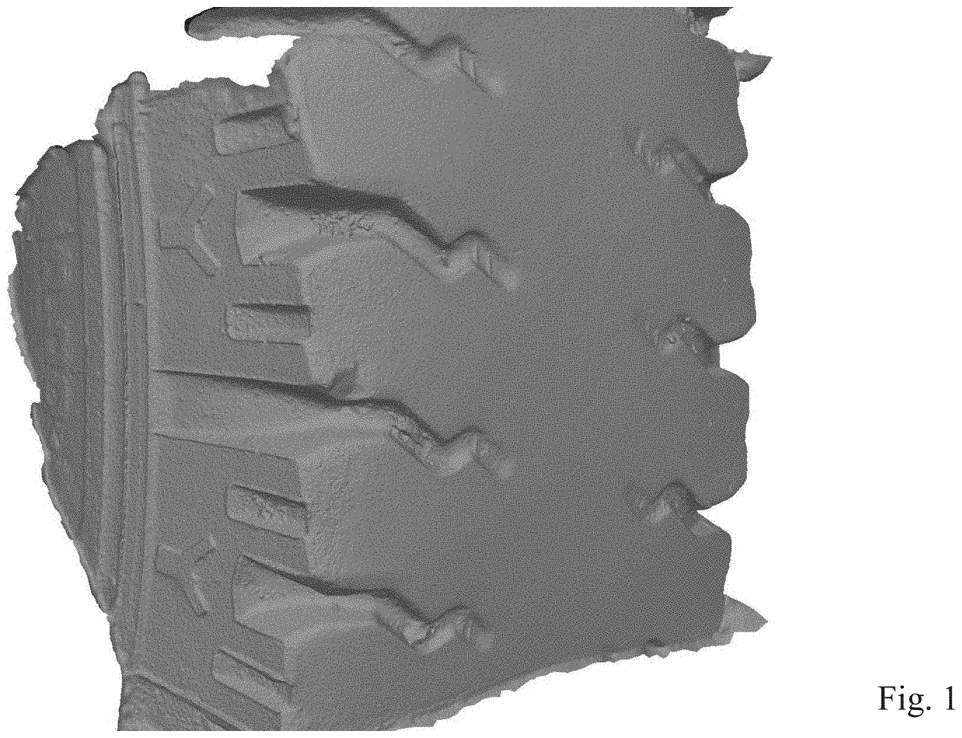

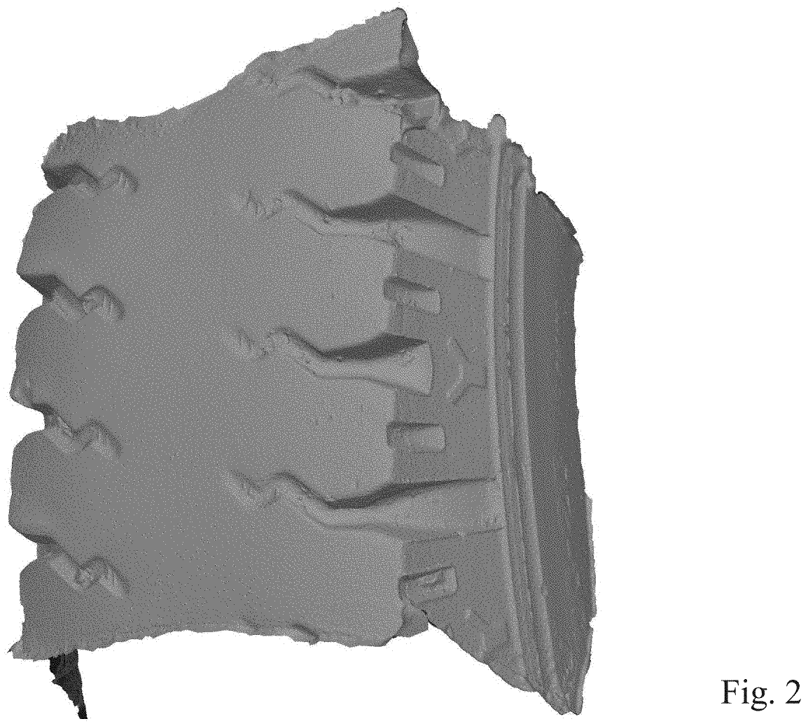

Referring now to FIGS. 1 and 2, a particular example embodiment is illustrated. FIGS. 1 and 2 are two views of a 3D scan of a tire portion generated from images. In this particular embodiment, the 3D scans are generated using photogrammetry, which involves taking still images from multiple viewpoints of the tire patch and generating the 3D scan.

Referring still to FIGS. 1 and 2, the tire analysis system of an example embodiment can receive or capture perception data corresponding to a 3D shape of a vehicle tire. For example, a photogrammetry-based measurement system can remotely acquire a series of still images or videos of the tire surface. This task can be accomplished by installing on the vehicle in the vicinity of the tire under analysis one or more cameras that can move along a specified path around the tire and acquire multiple images of the tire. The movement of the camera and the capture of the images or video can be triggered remotely either manually by a human or automatically using a computer program. Alternatively, one can also install one or more stationary cameras around the tire under analysis and cause the one or more stationary cameras to acquire one or more still images or videos of the tire. Using the captured still images or videos as perception data, the image analysis system of an example embodiment can generate an accurate 3D shape of the tire from the collection of still images or videos. This 3D shape of the tire can represent the unique signature of the tire.

In another example embodiment, a white-light scanner or LiDAR scanner can be used by a human operator or in an automated setup to acquire perception data of a tire under analysis. Using the white-light scanner perception data or LiDAR perception data, the image analysis system of an example embodiment can generate an accurate 3D shape of the tire, representing the unique tire signature, from the captured perception data.

Once the unique signature of a tire under analysis is generated from the received or captured perception data, the unique tire signature can be compared to a baseline tire signature retrieved from a baseline tire signature database or 3D tire shape database. As described in more detail below, the baseline tire signature database retains a plurality of baseline tire signatures for a variety of different types and sizes of tires under a variety of different conditions, such as inflation pressures, compressive loads, temperature, precipitation, terrain, wear patterns, etc. The baseline tire signature database can create an association between a particular unique signature of a tire and the inflation pressure and compressive load that created the unique tire signature. The unique tire signature of a tire under analysis can be compared to a baseline tire signature corresponding to a same or similar type and size of tire under similar conditions. Based on this comparison of elements in the baseline tire signature database, the tire analysis system can determine the particular combination of inflation pressure and compressive load that produces the 3D shape corresponding to the unique tire signature of the tire under analysis. In this manner, the tire analysis system of an example embodiment can determine the current inflation pressure and compressive load on a vehicle tire in real-time, without human intervention, and without contact with the tire.

In an example embodiment, the baseline tire signature database, and the baseline tire signature elements therein, can be generated and used in one of several ways. One way to generate the database-resident baseline tire signature elements, each representing specific combinations of inflation pressures and compressive loads, is described below.
1. Baseline Tire Signature Database: First, a representative portion (e.g., one pitch) of a particular baseline tire of the design of interest (e.g., a particular brand, model, year, wear history, composition, etc.) is scanned at various known inflation pressures and compressive loads to obtain baseline tire signatures (e.g., a 3D shape image of the tire) of the representative portion of the baseline tire at each known inflation pressure and compressive tire load. The actual values of the inflation pressures and compressive loads covered by this database may be chosen to span their respective ranges expected in the field, and ideally should be a bit larger to account for pathological cases that might be encountered occasionally. In this manner, each element of the baseline tire signature database can create an association between a particular unique signature of a baseline tire and the inflation pressure and compressive load that created the unique tire signature. Alternatively, if validated high-fidelity numerical models (e.g., finite-element models) are available, then these models can be used to populate some or all of the elements in the baseline tire signature database instead of manually scanning each baseline tire. The use of a validated high-fidelity numerical model is computational and has the advantage of being able to generate the elements of the baseline tire signature database for a large number of pressures and loads relatively easily when compared to the process of manually scanning each baseline tire, which is experimental or empirical.
2. Mathematical Modeling: Once the baseline tire signature database is initially populated with empirical elements as described above, the database content can be expanded to include derived elements as well. The derived elements can fill the gaps between the empirical data elements. In particular, the empirical relationships determined from the association between a particular unique signature of a baseline tire and the inflation pressure and compressive load that created the unique tire signature, as described above, can be derived to generate derived data elements. The derived data elements correspond to associations between signatures of the baseline tire and the corresponding inflation pressures and compressive loads that would create the tire signature, even though the derived data cases were not actually empirically tested. For example, mathematical techniques such as interpolation can be used to generate derived data elements from two or more empirical data elements. Additionally, the derived data elements can be generated from explicit formulae or models obtained using machine learning techniques. As a result, the derived unique signatures of the baseline tire can be obtained even for those cases that were not used in generating the empirical data elements.
3. Operational Tire Scan and Database Search: Once the baseline tire signature database is populated with empirical and derived baseline tire signature elements, the tire analysis system is able to initiate the processing for a tire under analysis in a real world operational context. In this case, the unique tire signature of a tire under analysis can be captured as described above. In particular, a scan of the tire under analysis, for which the current inflation pressure and compressive load needs to be determined, can be performed. Once the unique tire signature of the tire under analysis or tire scan is captured, the unique tire signature of the tire under analysis can be mathematically compared to baseline tire signature elements in the baseline tire signature database. As described in more detail below, one or more deviation maps can be generated to facilitate the comparison process. When a match is found between the unique tire signature of the tire under analysis and one of the baseline tire signature elements in the baseline tire signature database, the inflation pressure and compressive load of the matching baseline tire signature element can be associated with the inflation pressure and compressive load of the tire under analysis. In this manner, an example embodiment of the tire analysis system can determine the current inflation pressure and compressive load on a vehicle tire in real-time, without human intervention, and without contact with the tire. Once the current inflation pressure and compressive load of the tire under analysis is determined, the current inflation pressure and compressive tire load can be compared to data indicative of the safe operating ranges for the tire. If the current inflation pressure and/or compressive tire load is outside of the safe operating ranges for the tire, the tire analysis system can automatically send user notifications to alert a user to the unsafe tire condition. Additionally, the tire analysis system can automatically send autonomous vehicle control commands to an autonomous vehicle control system to cause the autonomous vehicle to perform actions in response to the unsafe tire condition (e.g., slow down, stop, divert to a safe location, etc.).

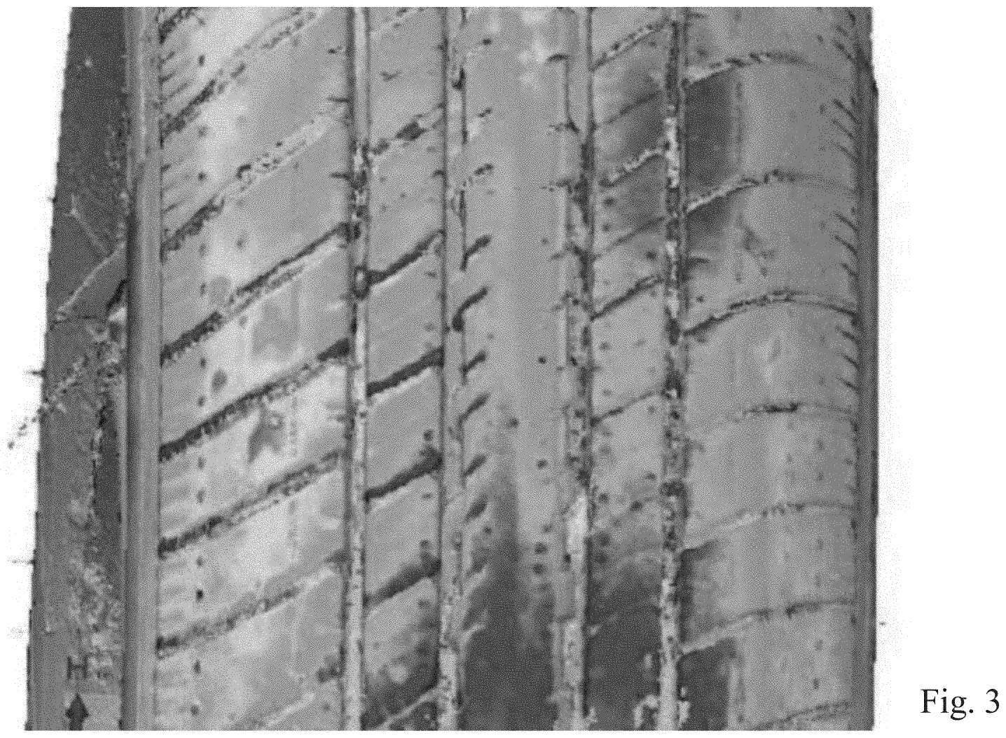

Referring now to FIG. 3, a sample view of a tire shows a deviation map indicating specific values of deviation between the 3D shape (e.g., the unique tire signature) of the tire under analysis and the 3D shape of a corresponding baseline tire (e.g., the baseline tire signature). In the example embodiment, the unique tire signature of the tire under analysis can be aligned with the corresponding baseline tire signature. The tire analysis system of an example embodiment can align the field tire scan (e.g., the unique tire signature of the tire under analysis) obtained under unknown inflation pressure and compression load with a baseline tire signature at a known specific inflation pressure and compression load and compute the difference between the unique tire signature of the tire under analysis and the baseline tire signature, resulting in a deviation map. An example deviation map is shown in FIG. 3. Different colors or shades of gray can be used to indicate a specific value of deviation between the unique tire signature of the tire under analysis and the baseline tire signature. This process can be repeated with different baseline tire signatures from the baseline tire signature database to create a deviation map indicative of a minimal level of deviation between the unique tire signature of the tire under analysis and a corresponding baseline tire signature. Once a matching baseline tire signature with a minimal level of deviation is found, the specific inflation pressure and compression load corresponding to the matching baseline tire signature can be associated with the tire under analysis. In another example embodiment, two or more of the closest matching baseline tire signatures with a least level of deviation spanning their respective ranges can be used in an interpolation process to derive the best approximation of the specific inflation pressure and compression load corresponding to the tire under analysis. In an alternative embodiment, machine learning techniques (e.g., support vector machines (SVM), convolutional neural networks (CNN), or the like) can be used to analyze the unique tire signature of the tire under analysis with corresponding baseline tire signatures. The machine learning models can be trained on a wide range of tire signatures and corresponding inflation pressures and compression loads over a variety of different environmental and operating conditions such as temperature, precipitation, terrain, etc.

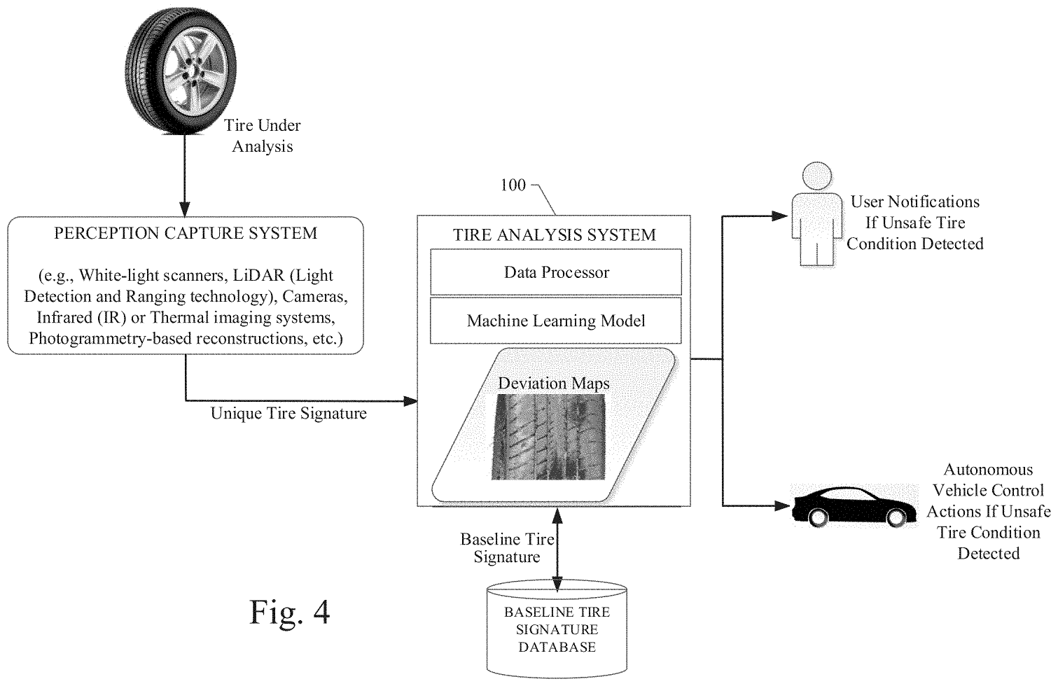

FIG. 4 is a structure diagram that illustrates example embodiments of systems as described herein. The tire analysis system 100 of an example embodiment can be configured as a software application executable by a data processor. The data processor can be in data communication with a perception capture system configured to capture or receive one or more scans of a tire under analysis. Various embodiments of the tire analysis system 100 as disclosed herein can be used with any perception capture system that can yield an accurate 3D scan of a portion of a vehicle tire. In various example embodiments, the perception capture system can include: white-light scanners, LiDAR (Light Detection and Ranging technology), cameras, infrared (IR) or thermal imaging systems, photogrammetry-based reconstructions, or the like. As shown in FIG. 4, the tire analysis system 100 of an example embodiment can receive a 3D scan of a portion of a vehicle tire corresponding to the unique signature of the tire under analysis from the perception capture system. The tire analysis system 100 can use the data processor and a machine learning model to compare the received unique signature of the tire under analysis with baseline tire signature elements of the baseline tire signature database as described above. When a match is found between the unique tire signature of the tire under analysis and one or more of the baseline tire signature elements in the baseline tire signature database, the inflation pressure and compressive load of the one or more matching baseline tire signature elements can be associated with the inflation pressure and compressive load of the tire under analysis. In this manner, an example embodiment of the tire analysis system 100 can determine the current inflation pressure and compressive load on a vehicle tire in real-time, without human intervention, and without contact with the tire. Once the current inflation pressure and compressive load of the tire under analysis is determined, the current inflation pressure and compressive tire load can be compared to data indicative of the safe operating ranges for the tire in the relevant environmental conditions. If the current inflation pressure and/or compressive tire load is outside of the safe operating ranges for the tire, the tire analysis system can automatically send user notifications to alert a user to the detection of the unsafe tire condition. Additionally, the tire analysis system can automatically send autonomous vehicle control commands to an autonomous vehicle control system to cause the autonomous vehicle to perform actions in response to the detection of the unsafe tire condition (e.g., slow down, stop, divert to a safe location, activate hazard lights, etc.).

Various embodiments of the tire analysis system 100 as disclosed herein can be used with any of a variety of mathematical techniques that can be used to construct and derive the baseline tire signature database, compare a unique tire signature of a tire under analysis to a baseline tire signature corresponding to a same or similar type and size of tire under similar conditions, and determine an unknown inflation pressure and compressive load from a scan of a portion of a tire under analysis.

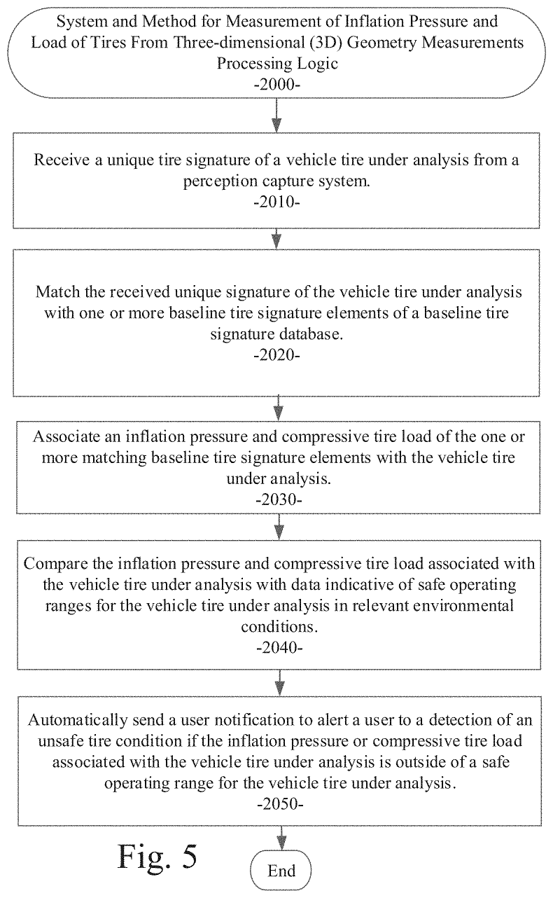

Referring now to FIG. 5, a processing flow diagram illustrates an example embodiment of a method implemented by the example embodiments as described herein. The method 2000 of an example embodiment can be configured to: receive a unique tire signature of a vehicle tire under analysis from a perception capture system (processing block 2010); match the received unique signature of the vehicle tire under analysis with one or more baseline tire signature elements of a baseline tire signature database (processing block 2020); associate an inflation pressure and compressive tire load of the one or more matching baseline tire signature elements with the vehicle tire under analysis (processing block 2030); compare the inflation pressure and compressive tire load associated with the vehicle tire under analysis with data indicative of safe operating ranges for the vehicle tire under analysis in relevant environmental conditions (processing block 2040); and automatically send a user notification to alert a user to a detection of an unsafe tire condition if the inflation pressure or compressive tire load associated with the vehicle tire under analysis is outside of a safe operating range for the vehicle tire under analysis (processing block 2050).

FIG. 6 shows a diagrammatic representation of a machine in the example form of a mobile computing and/or communication system 700 within which a set of instructions when executed and/or processing logic when activated may cause the machine to perform any one or more of the methodologies described and/or claimed herein. In alternative embodiments, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be a personal computer (PC), a laptop computer, a tablet computing system, a Personal Digital Assistant (PDA), a cellular telephone, a smartphone, a web appliance, a set-top box (STB), a network router, switch or bridge, or any machine capable of executing a set of instructions (sequential or otherwise) or activating processing logic that specify actions to be taken by that machine. Further, while only a single machine is illustrated, the term “machine” can also be taken to include any collection of machines that individually or jointly execute a set (or multiple sets) of instructions or processing logic to perform any one or more of the methodologies described and/or claimed herein.

The example mobile computing and/or communication system 700 includes a data processor 702 (e.g., a System-on-a-Chip (SoC), general processing core, graphics core, and optionally other processing logic) and a memory 704, which can communicate with each other via a bus or other data transfer system 706. The mobile computing and/or communication system 700 may further include various input/output (I/O) devices and/or interfaces 710, such as a touchscreen display, an audio jack, and optionally a network interface 712. In an example embodiment, the network interface 712 can include one or more radio transceivers configured for compatibility with any one or more standard wireless and/or cellular protocols or access technologies (e.g., 2nd (2G), 2.5, 3rd (3G), 4th (4G) generation, and future generation radio access for cellular systems, Global System for Mobile communication (GSM), General Packet Radio Services (GPRS), Enhanced Data GSM Environment (EDGE), Wideband Code Division Multiple Access (WCDMA), LTE, CDMA2000, WLAN, Wireless Router (WR) mesh, and the like). Network interface 712 may also be configured for use with various other wired and/or wireless communication protocols, including TCP/IP, UDP, SIP, SMS, RTP, WAP, CDMA, TDMA, UMTS, UWB, WiFi, WiMax, Bluetooth™, IEEE 802.11x, and the like. In essence, network interface 712 may include or support virtually any wired and/or wireless communication mechanisms by which information may travel between the mobile computing and/or communication system 700 and another computing or communication system via network 714.

The memory 704 can represent a machine-readable medium on which is stored one or more sets of instructions, software, firmware, or other processing logic (e.g., logic 708) embodying any one or more of the methodologies or functions described and/or claimed herein. The logic 708, or a portion thereof, may also reside, completely or at least partially within the processor 702 during execution thereof by the mobile computing and/or communication system 700. As such, the memory 704 and the processor 702 may also constitute machine-readable media. The logic 708, or a portion thereof, may also be configured as processing logic or logic, at least a portion of which is partially implemented in hardware. The logic 708, or a portion thereof, may further be transmitted or received over a network 714 via the network interface 712. While the machine-readable medium of an example embodiment can be a single medium, the term “machine-readable medium” should be taken to include a single non-transitory medium or multiple non-transitory media (e.g., a centralized or distributed database, and/or associated caches and computing systems) that stores the one or more sets of instructions. The term “machine-readable medium” can also be taken to include any non-transitory medium that is capable of storing, encoding or carrying a set of instructions for execution by the machine and that cause the machine to perform any one or more of the methodologies of the various embodiments, or that is capable of storing, encoding or carrying data structures utilized by or associated with such a set of instructions. The term “machine-readable medium” can accordingly be taken to include, but not be limited to, solid-state memories, optical media, and magnetic media.

As described herein for various example embodiments, a system and method for measurement of inflation pressure and load of tires from three-dimensional (3D) geometry measurements are disclosed. In various embodiments, a software application program is used to enable the capture and processing of images on a computing or communication system, including mobile devices. As described above, in a variety of contexts, the various example embodiments can be configured to automatically capture images of a vehicle tire being analyzed, all from the convenience of a portable electronic device, such as a smartphone. This collection of images can be processed and results can be distributed to a variety of network users. As such, the various embodiments as described herein are necessarily rooted in computer and network technology and serve to improve these technologies when applied in the manner as presently claimed. In particular, the various embodiments described herein improve the use of mobile device technology and data network technology in the context of automated object visual inspection via electronic means.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A system comprising:
a data processor;
a perception capture system in data communication with the data processor, the perception capture system configured to capture or receive one or more scans of a vehicle tire under analysis; and
a tire analysis system executable by the data processor, the tire analysis system configured to:
receive a unique tire signature of the vehicle tire under analysis from the perception capture system;
match the received unique signature of the vehicle tire under analysis with one or more baseline tire signature elements of a baseline tire signature database;
associate an inflation pressure and compressive tire load of the one or more matching baseline tire signature elements with the vehicle tire under analysis;
compare the inflation pressure and compressive tire load associated with the vehicle tire under analysis with data indicative of safe operating ranges for the vehicle tire under analysis in relevant environmental conditions; and
automatically send a user notification to alert a user to a detection of an unsafe tire condition if the inflation pressure or compressive tire load associated with the vehicle tire under analysis is outside of a safe operating range for the vehicle tire under analysis.

2. The system of claim 1 wherein the tire analysis system being further configured to operate without human intervention and without contact with the vehicle tire under analysis.

3. The system of claim 1 wherein the perception capture system includes a tire scanning device from the group consisting of: a white-light scanner, a LiDAR (Light Detection and Ranging) device, a camera, an infrared (IR) or thermal imaging system, and a photogrammetry-based reconstruction device.

4. The system of claim 1 wherein the tire analysis system being further configured to create the baseline tire signature database by scanning a plurality of portions of representative baseline tires at known inflation pressures and compressive tire loads.

5. The system of claim 4 wherein the tire analysis system being further configured to create the baseline tire signature database by deriving the inflation pressures and compressive tire loads from the scanned portions of the representative baseline tires.

6. The system of claim 1 wherein the tire analysis system being further configured to use a trained machine learning model to match the received unique signature of the vehicle tire under analysis with one or more baseline tire signature elements of the baseline tire signature database.

7. A method comprising:
receiving a unique tire signature of a vehicle tire under analysis from a perception capture system;
matching the received unique signature of the vehicle tire under analysis with one or more baseline tire signature elements of a baseline tire signature database;
associating an inflation pressure and compressive tire load of the one or more matching baseline tire signature elements with the vehicle tire under analysis;
comparing the inflation pressure and compressive tire load associated with the vehicle tire under analysis with data indicative of safe operating ranges for the vehicle tire under analysis in relevant environmental conditions; and
automatically sending a user notification to alert a user to a detection of an unsafe tire condition if the inflation pressure or compressive tire load associated with the vehicle tire under analysis is outside of a safe operating range for the vehicle tire under analysis.

8. The method of claim 7 being performed without human intervention and without contact with the vehicle tire under analysis.

9. The method of claim 7 wherein the perception capture system includes a tire scanning device from the group consisting of: a white-light scanner, a LiDAR (Light Detection and Ranging) device, a camera, an infrared (IR) or thermal imaging system, and a photogrammetry-based reconstruction device.

10. The method of claim 7 including creating the baseline tire signature database by scanning a plurality of portions of representative baseline tires at known inflation pressures and compressive tire loads.

11. The method of claim 10 including creating the baseline tire signature database by deriving the inflation pressures and compressive tire loads from the scanned portions of the representative baseline tires.

12. The method of claim 7 including using a trained machine learning model to match the received unique signature of the vehicle tire under analysis with one or more baseline tire signature elements of the baseline tire signature database.

13. A non-transitory machine-useable storage medium embodying instructions which, when executed by a machine, cause the machine to:
receive a unique tire signature of a vehicle tire under analysis from a perception capture system;
match the received unique signature of the vehicle tire under analysis with one or more baseline tire signature elements of a baseline tire signature database;
associate an inflation pressure and compressive tire load of the one or more matching baseline tire signature elements with the vehicle tire under analysis;
compare the inflation pressure and compressive tire load associated with the vehicle tire under analysis with data indicative of safe operating ranges for the vehicle tire under analysis in relevant environmental conditions; and
automatically send a user notification to alert a user to a detection of an unsafe tire condition if the inflation pressure or compressive tire load associated with the vehicle tire under analysis is outside of a safe operating range for the vehicle tire under analysis.

14. The non-transitory machine-useable storage medium of claim 13 being further configured to operate without human intervention and without contact with the vehicle tire under analysis.

15. The non-transitory machine-useable storage medium of claim 13 wherein the perception capture system includes a tire scanning device from the group consisting of: a white-light scanner, a LiDAR (Light Detection and Ranging) device, a camera, an infrared (IR) or thermal imaging system, and a photogrammetry-based reconstruction device.

16. The non-transitory machine-useable storage medium of claim 13 being further configured to create the baseline tire signature database by scanning a plurality of portions of representative baseline tires at known inflation pressures and compressive tire loads.

17. The non-transitory machine-useable storage medium of claim 16 being further configured to create the baseline tire signature database by deriving the inflation pressures and compressive tire loads from the scanned portions of the representative baseline tires.

18. The non-transitory machine-useable storage medium of claim 13 being further configured to use a trained machine learning model to match the received unique signature of the vehicle tire under analysis with one or more baseline tire signature elements of the baseline tire signature database.
